(19) United States
(12) Patent Application Publication
(10) Pub. No.: US 2026/0164592 A1
(43) Pub. Date: Jun. 11, 2026

(54) MOUNTING BRACKET FOR A SUPERCOMPUTER CABINET

(71) Applicant: BULL SAS, LES CLAYES-SOUS-BOIS (FR)

(72) Inventors: Levon MARGARIAN, ANGERS (FR); Antoine ROCHEREAU, ANGERS (FR)

(73) Assignee: BULL SAS, LES CLAYES-SOUS-BOIS (FR)

(21) Appl. No.: 19/405,935

(22) Filed: Dec. 2, 2025

(30) Foreign Application Priority Data
Dec. 6, 2024 (EP) 24307048.9

(51) Int. Cl. H05K 7/14

(52) U.S. Cl. CPC H05K 7/1489; H05K 7/1492

(57) ABSTRACT

The invention relates to a mounting bracket (30) for a supercomputer cabinet (1), comprising an outer frame (10), a support frame (20), compute blades (22) and a power supply unit (40) attached to said mounting bracket (30), said mounting bracket (30) comprising a fixed part (31) and an offset part (32), said fixed part (31) being configured to be mounted on the outer frame (10) of the cabinet (1) and to accommodate said offset part (32), the offset part (32) comprising a main portion (321) configured to be adjustably mounted on the fixed part (31) and a secondary portion (322) connected perpendicular to the main portion (321) and configured to be attached on said support frame (10) and to accommodate the power supply unit (40).

This application claims priority to European Patent Application Number 24307048.9, filed 6 Dec. 2024, the specification of which is hereby incorporated herein by reference.

### BACKGROUND OF THE INVENTION

### Field of the Invention

At least one embodiment of the invention relates to the field of supercomputer cabinets and more specifically concerns a mounting system for a supercomputer cabinet.

### Description of the Related Art

As computing needs grow, so do the number of data centers seeking to improve the performance of their hardware.

Despite advances in miniaturization, growing demand is leading to an increase in the number of components in the cabinets, which in turn means that supercomputer cabinets are increasingly cluttered, complicating maintenance operations.

Similarly, the increase in the number of components and their need for electrical power means a greater demand for power supplies, which in turn means a need for more power supply units in these supercomputer cabinets. As these components need to be cooled, the cooling systems also take up more space.

One obvious solution is to increase the size of supercomputer cabinets to accommodate the increase in components and power requirements, or to increase the number of supercomputer cabinets. However, this increase means that the environmental footprint of data centers is multiplied, due to their size and power consumption, which would be disadvantageous in terms of today's climate and environmental challenges.

Another solution is to offer specific cabinet shapes that are already optimized for their predetermined use. However, these cabinets are optimized for a certain type of equipment and a specific internal layout. As soon as the cabinets have to accommodate components outside this range, the optimal layout is no longer achievable. This type of device does not solve problems beyond these specific cases.

Thus, there is a need for a simple, effective solution to at least partially overcome these drawbacks.

### BRIEF SUMMARY OF THE INVENTION

To this end, at least one embodiment of the invention first of all has an object of a mounting bracket for a supercomputer cabinet, said cabinet having a parallelepiped shape comprising a front face, a rear face, two side faces, an outer frame, a support frame configured to accommodate a plurality of compute blades vertically stacked and configured to be inserted into and removed from said cabinet by sliding through the rear face of the cabinet, and at least one power supply unit configured to supply power to the compute blade components and to be attached to said mounting bracket, said mounting bracket being remarkable in that it comprises a fixed part and an offset part, said fixed part being configured to be mounted on the outer frame of the cabinet, extending in a plane parallel to the plane of the side face, and to accommodate said offset part, the offset part comprising a main portion configured to be adjustably mounted on the fixed part extending in a plane parallel to the plane of said fixed part and a secondary portion connected to the main portion extending perpendicular to the plane of said main portion, said secondary portion being configured to be attached to said support frame and to accommodate the at least one power supply unit.

The mounting bracket according to one or more embodiments of the invention enables the power supply unit(s) required for operating the supercomputer cabinet to be attached between the outer frame and the supporting frame by moving them in deeper, thus making use of space that is unoccupied in standard cabinets of the prior art. The mounting bracket also allows the power supply unit connectors to face the rear of the cabinet, rather than the inside, thus reducing the risk of damaging the equipment when inserting or removing the compute blades. Lastly, the modular nature of the mounting bracket, thanks to the adjustable attachment of the offset part to the fixed part, means that the mounting bracket can be adapted to different types of cabinet, depending on the user's IT requirements.

In at least one embodiment, the secondary portion of the offset part is made from the same material as the main portion. This configuration makes manufacturing the offset part simpler and more efficient.

Advantageously, the main portion of the offset part is configured to be attached to the fixed part via a screw-nut system. This system is simple and practical to use when assembling the cabinet.

Preferably, in at least one embodiment, the fixed part comprises at least one fastening groove through which the screw-nut assembly is attached. This allows the offset part to be fastened to the fixed part in two stages: first, the operator places the screw in the fastening groove and the fastening hole and adjusts the position, thus holding the offset part in place during adjustment, and once the correct position has been found, the nut is tightened to attach and lock the offset part. This allows precise, easy-to-use adjustment.

In at least one embodiment, the main portion of the offset part is configured to be attached to the fixed part via another mounting system, such as a mounting rail, clip-on, etc.

Advantageously, in one or more embodiments, the fixed part and the main portion of the offset part comprise a set of cable-holding perforations. These cable-holding perforations provide efficient arrangements for the many cables that connect the compute blades to one another and to external elements.

Preferentially, in one or more embodiments. the fixed part comprises a reinforcement portion that increases the rigidity of the fixed part, in particular to prevent deformation under the weight of the power supply unit.

Again preferentially, in one or more embodiments. the reinforcement portion is achieved by bending and takes the form of a bend extending along all or part of the length of the longitudinal edge of the fixed part. This longitudinal bend is simple to implement and can be used as a fastening element to be inserted into a corresponding groove in one of the rear uprights of the outer frame to further reinforce the rigidity of the mounting bracket.

Alternatively, in at least one embodiment, the reinforcement portion could be a member mounted on the fixed part, in particular to enable the fixed part to be attached to the cabinet's outer frame while conferring additional rigidity to the part.

Advantageously, in one or more embodiments, the offset part comprises at least one through opening. This opening reduces the weight of the support element, while enabling offset parts to be produced with a greater extension to suit specific cabinet layouts.

In at least one embodiment, the fixed part and the offset part are made of a metallic material, such as aluminum.

In at least one embodiment, the main portion comprises a first plate and a second plate, said first and second plates extending in two parallel planes and being attached to one another, for example by welding, or being made of the same material, for example by bending or molding.

At least one embodiment of the invention also relates to a supercomputer cabinet having a parallelepiped shape comprising a front face, a rear face, two side faces, an outer frame, a support frame configured to accommodate a plurality of compute blades vertically stacked and configured to be inserted and removed from said cabinet by sliding through the rear face of the cabinet, at least one power supply unit configured to supply power to the compute blade components, and at least one mounting bracket attached to the outer frame of the cabinet. This cabinet features an optimized interior layout thanks to the mounting bracket, and presents less risk of damaging the power supply units when inserting and removing the compute blades.

By way of one or more embodiments of the invention also relates to a method of assembling a supercomputer cabinet as described, implemented by an operator and comprising the steps of:
assembling the outer frame of the supercomputer cabinet,
assembling the support frame, attached to the outer frame,
fastening the fixed part of the mounting bracket to the outer frame,
positioning the offset part of the mounting bracket in relation to the fixed part,
attaching the offset part to the fixed part and to the support frame,
attaching the power supply unit to the offset part thus attached,
inserting the plurality of compute blades vertically stacked in the support frame,
connecting the inserted compute blades to the attached power supply unit to provide the compute blades with electrical power.

This method enables the cabinet to be assembled simply, quickly and efficiently with at least one mounting bracket according to at least one embodiment of the invention.

### BRIEF DESCRIPTION OF THE DRAWINGS

Further features and advantages of the one or more embodiments of the invention will become apparent from the following description. This is purely illustrative and should be read in conjunction with the appended drawings wherein:

FIG. 1 schematically shows a perspective view of a supercomputer cabinet comprising a mounting bracket according to one or more embodiments of the invention.

FIG. 2 schematically shows a view of the fixed part of the mounting bracket according to one or more embodiments of the invention.

FIG. 3 schematically shows a view of a first example of the offset part of the mounting bracket according to one or more embodiments of the invention.

FIG. 4 schematically shows a view of a second example of the offset part of the mounting bracket according to one or more embodiments of the invention.

FIG. 5 schematically shows a view of the mounting bracket with the offset part attached to the fixed part and a power supply unit attached to the offset part, according to one or more embodiments of the invention.

FIG. 6 schematically shows the method of assembling a supercomputer cabinet according to one or more embodiments of the invention.

### DETAILED DESCRIPTION OF THE INVENTION

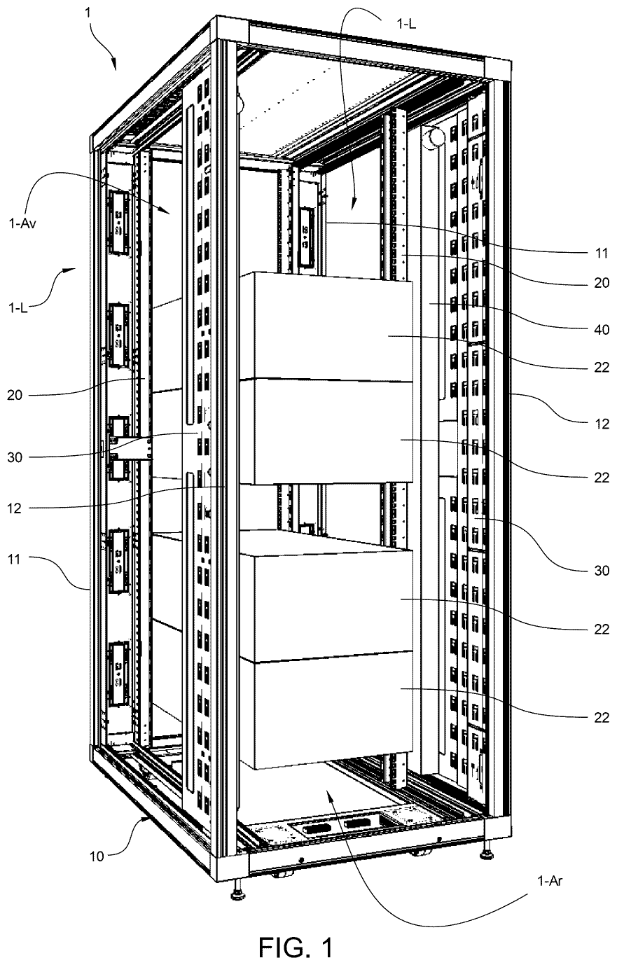

FIG. 1 schematically shows an example of a supercomputer cabinet 1 comprising a mounting bracket 30 according to one or more embodiments of the invention.

### Cabinet 1

As shown in FIG. 1, in at least one embodiment, the cabinet 1 is parallelepiped in shape and comprises an outer frame 10, a support frame 20, two mounting brackets 30 and a power supply unit 40.

The outer frame 10 of the cabinet 1 comprises vertical and horizontal uprights forming the outer edges of the cabinet 1. These uprights define a front face 1-Av, a rear face 1-Ar and two side faces 1-L.

In particular, the outer frame 10 comprises two front uprights 11 extending vertically on either side of the front face 1-Av, and two rear uprights 12 extending vertically on either side of the rear face 1-Ar.

The support frame 20 comprises a plurality of compute blades 22 that are stacked upon one another. The compute blades 22 can be inserted and removed from cabinet 1 by sliding through the rear face 1-Ar.

The compute blades 22 contain the computer components needed to process a large amount of computer data.

Each mounting bracket 30 comprises a fixed part 31 and an offset part 32. In a at least one embodiment, the fixed part 31 and the offset part 32 are one-piece metal parts, made of aluminum for example.

The fixed part 31 is attached to the outer frame 10 of the cabinet 1, extending in a plane parallel to the plane of one of the side faces 1-L.

Advantageously, the cabinet 1 comprises two mounting brackets 30, located on either side of the support frame 20, parallel to the two side faces 1-L.

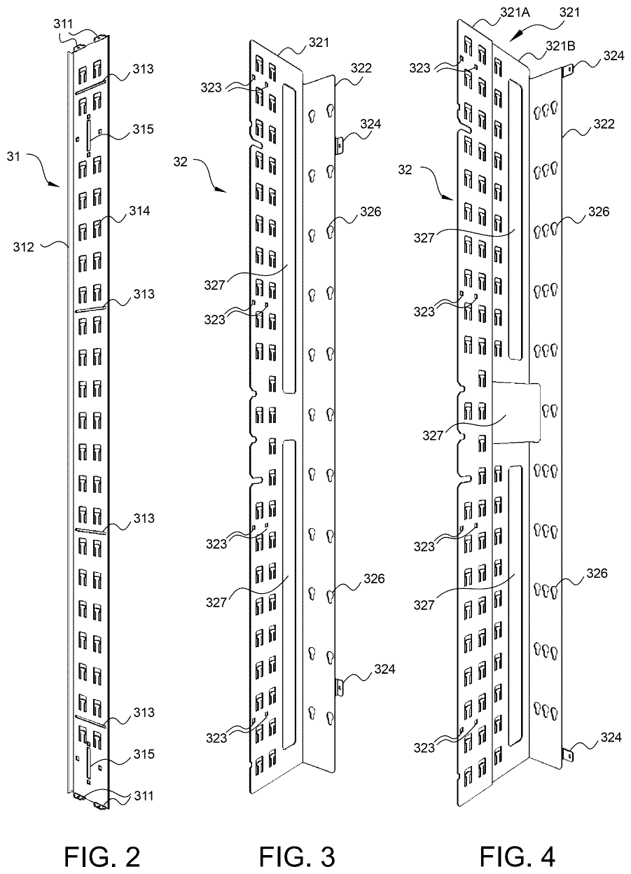

The fixed part 31 comprises a set of fasteners 311 which enable the assembly of the mounting bracket 30 to the outer frame 10. As shown in FIG. 2, by way of one or more embodiments. these fasteners 311 are metal portions bent perpendicular to the plane wherein the fixed part 31 extends and comprising holes which enable the top and bottom of the fixed part 31 to be screwed to the outer frame 10.

As shown in FIG. 1, by way of one or more embodiments, the fixed part 31 is attached at the top and bottom to the outer frame 10.

As shown in FIG. 2, in at least one embodiment, the fixed part 31 includes a longitudinal bend 312 which ensures the rigidity of the fixed part 31. The longitudinal bend 312 is also inserted into the rail of the rear upright 12 to secure the mounting bracket 30.

The fixed part 31 comprises a plurality of fastening grooves 313. These fastening grooves 313 extend perpendicular to the longitudinal direction of the fixed part 31 and are designed to accommodate a screw-nut assembly for fastening the offset part 32.

Preferably, the fixed part 31 comprises a set of cable-holding perforations 314 and a set attachment perforations 315 for the liquid system.

The cable-holding perforations 314 guide and hold the cables connecting the compute blades 22 to other cabinets 1 or to computers, the Internet, etc.

As shown in FIG. 2, in at least one embodiment, these cable-holding perforations 314 consist of rectangular openings in the fixed part 31, into which extends a tongue of the same material ending in a flared portion. The tongue is offset from the plane of the fixed part 31.

The attachments perforations 315 are used to attach the cooling system lines for the compute blades 22.

As shown in FIGS. 3 and 4, by way of one or more embodiments, the offset part 32 comprises a main portion 321 and a secondary portion 322.

The main portion 321 is adjustably assembled to the fixed part 31 extending in a plane parallel to the plane of said fixed part 31, and it comprises a set of attachment holes 323 which allow the offset part 32 to be attached to the fixed part 31 by threading a screw-nut assembly through said attachment holes 323 and fastening grooves 313.

Like the fixed part 31, the main portion 321 includes a set of cable-holding perforations 325. As shown in FIGS. 3 and 4, by way of one or more embodiments. the cable-holding perforations 325 are arranged in a grid comprising a plurality of rows and columns.

As shown in FIG. 3, in at least one embodiment, the main portion 321 comprises two columns of cable-holding perforations 325.

As shown in FIG. 4, in at least one embodiment, the main portion 321 is wider and comprises a first plate 321A and a second plate 321B, said first plate 321A and second plate 321B extending in two parallel planes and being attached to one another, for example by welding. Two columns of cable-holding perforations 325 are formed in the first plate 321A and one is formed in the second plate 321B.

As shown in FIGS. 3 and 4, in at least one embodiment, the main portion 321 comprises one or more through openings 327, which lighten the weight of the mounting bracket 30 while still having a substantial extension.

As shown in the offset part 32 shown in FIG. 4, by way of one or more embodiments. the through openings 327 are located on the second plate 321B.

As in FIGS. 3 and 4, in at least one embodiment, the secondary portion 322 is made from the same material as the main portion 321, so that the secondary portion 322 extends perpendicular to the plane of the main portion 321.

Advantageously, the secondary portion 322 is bent relative to the main portion 321, or directly molded.

Alternatively, in one or more embodiments, the secondary portion 322 is attached to the main portion 321 or welded.

The secondary portion 322 can be bent or molded differently depending on whether the mounting bracket 30 is positioned to the right or left of the rear face 1-Ar.

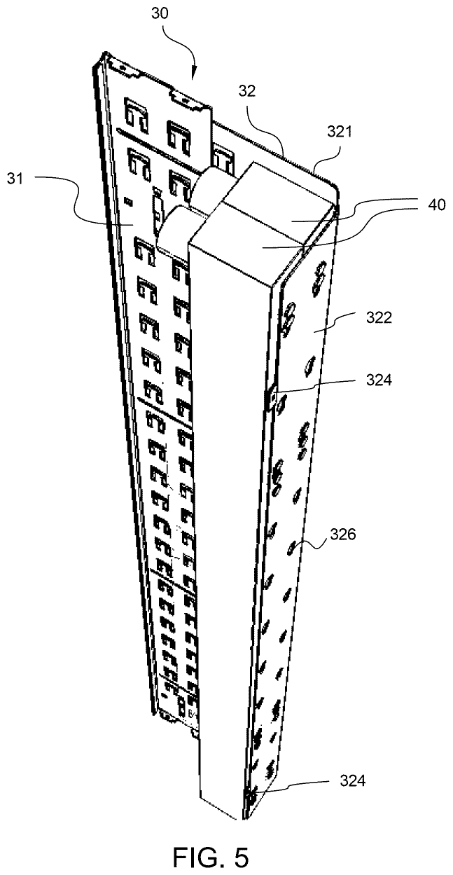

The secondary portion 322 comprises fasteners 324 for mounting the power supply unit 40 so that the set of connectors faces the rear face 1-Ar, as shown in FIG. 5. according to one or more embodiments.

As shown in FIGS. 3 and 4, in at least one embodiment. the fasteners 324 are orifices comprising a wide part and a narrow part. The power supply unit 40 then comprises hooks configured to be inserted into the wide part of the hole and to lock by gravity into the narrowed part in order to secure the power supply unit 40 when using the cabinet 1 as shown in FIG. 5, according to one or more embodiments.

As shown in FIGS. 3 and 4, in at least one embodiment, the fasteners 324 are arranged in a grid comprising a plurality of rows and columns. Each column holds a power supply unit 40.

As shown in FIG. 3, in at least one embodiment, the secondary portion 322 comprises two columns of fasteners 324.

As shown in FIG. 4, in at least one embodiment, the secondary portion 322 is wider and comprises three columns of fasteners 324.

Preferably, the secondary portion 322 comprises at least one attachment portion 326 for attachment to the support frame 20. In one or more embodiments, these attachment portions 326 are metal portions bent perpendicular to the plane wherein the secondary portion 322 extends and comprising a hole through which the secondary portion 322 can be screwed to the support frame 20.

Cabinet 1 includes a power supply unit 40. The power supply unit 40 is parallelepiped in shape, with a reduced cross-section and a height similar to that of the cabinet 1.

The power supply unit 40 comprises a connection face and an attachment face. The connection face comprises connectors designed to be electrically connected to the compute blades 22 to ensure their power supply. The attachment face is opposite to the connection face and comprises fasteners complementary to the fasteners 324 of the secondary part 322 as shown in FIG. 5, according to one or more embodiments.

### Example of Implementation

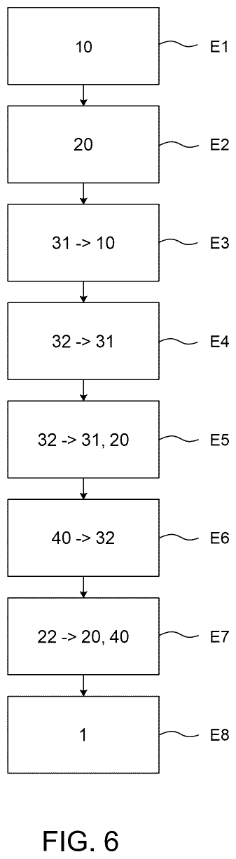

The method for assembling the cabinet 1 with at least one mounting bracket 30 is shown in FIG. 6, according to one or more embodiments of the invention.

In step E1, the operator assembles the outer frame 10 of the cabinet 1 by fastening the uprights, in particular the front uprights 11 and the rear uprights 12.

Then, in step E2, the operator assembles the support frame 20 of the cabinet 1 inside the outer frame 10.

In step E3, the fixed part 31 of the mounting bracket 30 is attached to the outer frame 10. The fixed part 31 is screwed through the holes of the fasteners 311, and the longitudinal bend 312 is inserted into the rail of one of the rear uprights 12 of the outer frame 10 as shown in the figures, by way of at least one embodiment.

In step E4, the offset part 32 is positioned relative to the fixed part 31 so as to match the desired characteristics of the cabinet 1, in particular the number of power supply units 40 and the size of the compute blades 22. Different embodiments of the offset part 32 can be used, as shown in FIGS. 3 and 4, according to one or more embodiments.

Once the offset part 32 has been positioned, it is attached to the fixed part 31 in step E5. In at least one embodiment shown in the figures, screw-nut assemblies are tightened through fastening grooves 313 and fastening holes 323. The offset part 32 is also screwed to the support frame 10 through the holes in the fasteners 326.

In step E6, the power supply unit 40 is mounted on the offset part 32, which is attached to the outer frame 10 and the support frame 20. In at least one embodiment shown in the figures, the power supply unit 40 is positioned so that its fastening face faces the secondary part 322 of the offset part 32, and is then inserted into the fasteners 324 of the secondary part 322.

In step E7, the compute blades 22 are inserted so as to be vertically stacked in the support frame 20.

Finally, in step E8, the inserted compute blades 22 are electrically connected to the power supply unit 40 attached to the mounting bracket 30, in order to ensure their power supply and the operation of the cabinet 1.

The supercomputer cabinet 1 assembled in this way has an optimized internal space due to the mounting bracket 30, which allows the power supply units 40 to be offset in a space between the outer frame 10 and support frame 20 that is not being used. In addition, the mounting of the power supply unit 40 allows the connection face to be facing the rear face of the cabinet 1, enabling the compute blades 22 to be inserted and removed without the risk of hitting the connectors of the power supply unit 40. Finally, the mounting bracket 30 is easy to assemble in the cabinet 1, and can be designed in a variety of ways to take account of the specific dimensions and requirements of each cabinet 1.

1. A supercomputer cabinet, said supercomputer cabinet comprising:
a parallelepiped shape comprising
a front face,
a rear face,
two side faces,
an outer frame_ and
a support frame configured to accommodate a plurality of vertically stacked compute blades configured to be inserted and removed from said supercomputer cabinet by sliding through the rear face of the supercomputer cabinet,
at least one power supply unit configured to supply power to components of the plurality of vertically stacked compute blades and at least one mounting bracket,
the at least one mounting bracket comprising a fixed part and an offset part,
the fixed part is mounted on the outer frame of the supercomputer cabinet, extending in a plane parallel to a plane of a side face of the two side faces, and accommodating said offset part,
the offset part comprises a main portion adjustably mounted on the fixed part extending in a plane parallel to a plane of said fixed part and a secondary portion connected to the main portion extending perpendicular to the plane of said main portion, said secondary portion being attached to said support frame and accommodating the at least one power supply unit.

2. The supercomputer cabinet according to claim 1, wherein the secondary portion of the offset part is made of a same material as the main portion.

3. The supercomputer cabinet according to claim 1, wherein the main portion of the offset part is configured to be attached to the fixed part via a screw-nut system.

4. The supercomputer cabinet according to claim 3, wherein the fixed part comprises at least one fastening groove through which the screw-nut system is fastened.

5. The supercomputer cabinet according to claim 1, wherein the fixed part and the main portion of the offset part comprise a set of cable holding perforations.

6. The supercomputer cabinet according to claim 1, wherein the fixed part comprises a reinforcing portion.

7. The supercomputer cabinet according to claim 1, wherein the offset part comprises at least one through opening.

8. The supercomputer cabinet according to claim 1, wherein the fixed part and the offset part are made of a metallic material.

9. A method of assembling a supercomputer cabinet, implemented by an operator, the supercomputer cabinet comprising
a parallelepiped shape comprising
a front face,
a rear face,
two side faces.
an outer frame, and
a support frame configured to accommodate a plurality of vertically stacked compute blades configured to be inserted and removed from said supercomputer cabinet by sliding through the rear face of the supercomputer cabinet.
at least one power supply unit configured to supply power to components of the plurality of vertically stacked compute blades and at least one mounting bracket.
the at least one mounting bracket comprising a fixed part and an offset part.
the fixed part is mounted on the outer frame of the supercomputer cabinet, extending in a plane parallel to a plane of a side face of the two side faces, and accommodating said offset part.
the offset part comprises a main portion adjustably mounted on the fixed part extending in a plane parallel to a plane of said fixed part and a secondary portion connected to the main portion extending perpendicular to the plane of said main portion, said secondary portion being attached to said support frame and accommodating the at least one power supply unit, and
wherein the method comprises:
assembling the outer frame of the supercomputer cabinet,
assembling the support frame, attached to the outer frame,
attaching the fixed part of the at least one mounting bracket to the outer frame,
positioning the offset part of the at least one mounting bracket relative to the fixed part,
attaching the offset part to the fixed part and to the support frame,
attaching the at least one power supply unit to the offset part thus attached,
inserting the plurality of vertically stacked compute blades in the support frame,
connecting the plurality of vertically stacked compute blades that are inserted to the at least one power supply unit that is attached in order to supply power to the plurality of vertically stacked compute blades.
